(19) United States
(12) Patent Application Publication
(10) Pub. No.: US 2020/0035954 A1
(43) Pub. Date: Jan. 30, 2020

(54) LIGHT-EMITTING DEVICE

(71) Applicant: PIONEER CORPORATION, Bunkyo-ku, Tokyo (JP)

(72) Inventor: Ayako YOSHIDA, Bunkyo-ku, Tokyo (JP)

(21) Appl. No.: 16/337,877

(22) PCT Filed: Sep. 28, 2016
(86) PCT No.: PCT/JP2016/078569

§ 371 Date: Mar. 28, 2019

(51) Int. Cl. H01L 51/52; H01L 51/10; H01L 51/05

(52) U.S. Cl. CPC H01L 51/5271; H01L 51/0533; H01L 51/102

(57) ABSTRACT

A light-emitting device (10) includes a light-transmitting first base material (210), a light-transmitting second base material (220), and a plurality of light-emitting units (140). The light-emitting units (140) are located between the first base material (210) and the second base material (220). The light-emitting units (140) emit light having a peak at a first wavelength. In addition, the light-emitting device (10) includes a light-transmitting region located between the plurality of light-emitting units (140). The second base material (220) includes an optical function layer (170). The optical function layer (170) is a layer which particularly reflects light of the first wavelength.

### TECHNICAL FIELD

The present invention relates to a light-emitting device.

### BACKGROUND ART

In recent years, there has been progress in the development of light-emitting devices using organic EL. Such light-emitting devices are used as illumination devices or display devices and configured of an organic layer interposed between a first electrode and a second electrode. Generally, a transparent material is used for the first electrode, and a metal material is used for the second electrode.

One of the light-emitting devices which utilizes the organic EL is a technology described in Patent Document 1. In order to provide a display device using organic EL with optical transparency (or a “see-through” property), the technology in Patent Document 1 provides the second electrode only in a portion of a pixel. In such a structure, since a region located between a plurality of second electrodes transmits light, the display device can have optical transparency.

### RELATED ART DOCUMENT

### Patent Document

[Patent Document 1]: Japanese Unexamined Patent Application Publication No. 2011-23336

### SUMMARY OF THE INVENTION

In a light-emitting device of a light-transmitting type in which light is desired to be extracted only from one surface (a front surface), there is a case where a portion of light leaks out also from a surface on the opposite side (a rear surface). In this case, visually recognizing the opposite side from the rear surface side through the light-emitting device may become difficult, and a light extraction efficiency on the front surface may decrease.

An example of the problem to be solved by the present invention is to reduce a leakage of light from a surface opposite to a light-emitting surface in a light-transmitting-type light-emitting device.

### MEANS FOR SOLVING THE PROBLEM

The invention described in claim 1 is a light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which the reflecting layer has a higher light reflectance at the first wavelength than an average light reflectance within a wavelength range of equal to or higher than 400 nm and equal to or lower than 700 nm.

The invention described in claim 2 is a light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which a reflectance of the reflecting layer is equal to or greater than 30% with respect to light within a wavelength range between two wavelengths as upper and lower limits each having an intensity of one half of a peak intensity of the peak at the first wavelength.

The invention described in claim 3 is a light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which a wavelength having a maximum reflectance in a reflection spectrum of light of the reflecting layer within a wavelength range of equal to or greater than 400 nm and equal to or less than 700 nm is located within a wavelength range between two wavelengths as upper and lower limits each having an intensity of one half of a peak intensity of the peak at the first wavelength.

The invention described in claim 4 is a light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which when a maximum reflectance in a reflection spectrum of light of the reflecting layer within a wavelength range of equal to or greater than 400 nm and equal to or less than 700 nm is Rₘₐₓ, the first wavelength is included within the wavelength range having a reflectance of equal to or greater than Rₘₐₓ×0.5.

The invention described in claim 13 is a light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which the reflecting layer has a higher light reflectance at the first wavelength than an average reflectance within a wavelength range which is equal to or higher than 400 nm and equal to or lower than 700 nm.

The invention described in claim 14 is a light-emitting device including:

a plurality of light-emitting units located between a light-transmitting base material and a light-transmitting covering layer, the light-emitting units emitting light having a peak at a first wavelength; and

in which the covering layer includes a reflecting layer, and

in which a reflectance of the reflecting layer is equal to or greater than 30% with respect to light within a wavelength range between two wavelengths as upper and lower limits each having an intensity of one half of a peak intensity of the peak at the first wavelength.

The invention described in claim 15 is a light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which a wavelength having a maximum reflectance in a reflection spectrum of light of the reflecting layer within a wavelength range of equal to or greater than 400 nm and equal to or less than 700 nm is located within a wavelength range between two wavelengths as upper and lower limits each having an intensity of one half of a peak intensity of the peak at the first wavelength.

The invention described in claim 16 is a light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which when a maximum reflectance in a reflection spectrum of light of the reflecting layer within a wavelength range of equal to or greater than 400 nm and equal to or less than 700 nm is Rₘₐₓ, the first wavelength is included within the wavelength range having a reflectance which is equal to or greater than Rₘₐₓ×0.5.

### BRIEF DESCRIPTION OF THE DRAWINGS

The objects described above, and other objects, features and advantages are further made apparent by a suitable embodiment that will be described below and the following accompanying drawings.

FIG. 1 is a cross-sectional view of a configuration of a light-emitting device according to a first embodiment.

FIG. 2 is an enlarged view of a light-emitting unit of a light-emitting device.

FIG. 3 is a diagram of an example of an emission spectrum of a light-emitting unit.

FIG. 4 is a diagram of an example of a reflection spectrum of an optical function layer.

FIG. 5 is a diagram of an example of a light path in a light-emitting device.

FIG. 6 is a plan view of a light-emitting device.

FIG. 7 is a cross-sectional view of a configuration of a light-emitting device according to a second embodiment.

FIG. 8 is a cross-sectional view of a configuration of a light-emitting device according to a third embodiment.

FIG. 9 is a cross-sectional view of a configuration of a light-emitting device according to a fourth embodiment.

FIG. 10 is a cross-sectional view of a configuration of a light-emitting device according to a fifth embodiment.

FIG. 11 is a cross-sectional view of a configuration of a light-emitting device according to a sixth embodiment.

FIG. 12 is a plan view of a light-emitting device according to a sixth embodiment.

FIG. 13 is a cross-sectional view of a configuration of a light-emitting device according to a seventh embodiment.

FIG. 14 is a cross-sectional view of a configuration of a light-emitting device according to Example 1.

FIG. 15 is a plan view of the light-emitting device illustrated in FIG. 14.

### DESCRIPTION OF EMBODIMENTS

Embodiments of the present invention will be described below by referring to the drawings. Moreover, in all the drawings, the same constituent elements are given the same reference numerals, and descriptions thereof will not be repeated.

### First Embodiment

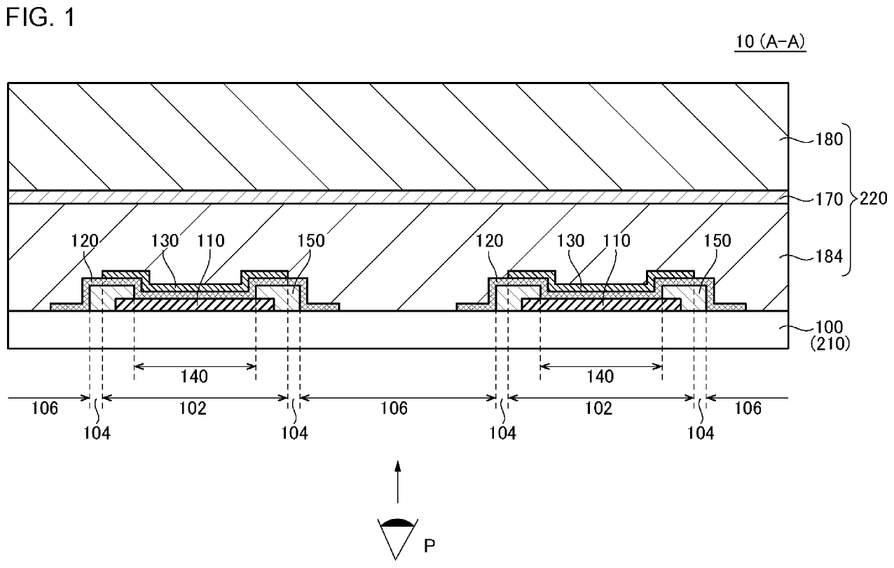

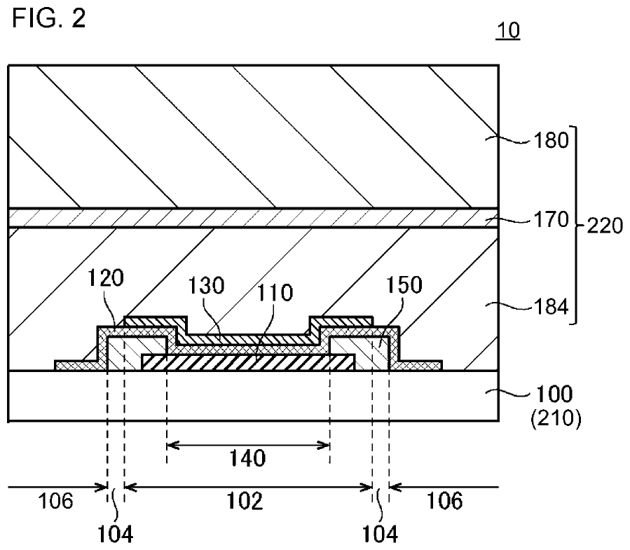

FIG. 1 is a cross-sectional view of a configuration of a light-emitting device 10 according to the first embodiment. An observer P observes a light-emitting surface of the light-emitting device 10 from a direction perpendicular to a substrate 100 in FIG. 1. FIG. 2 is an enlarged view of a light-emitting unit 140 of the light-emitting device 10.

The light-emitting device 10 includes a plurality of light-emitting units 140 located between a light-transmitting first base material 210 and a light-transmitting second base material 220. The light-emitting units 140 emit light having a peak at a first wavelength. In addition, the light-emitting device 10 includes a light-transmitting region located between the plurality of light-emitting units 140. Further, the second base material 220 includes an optical function layer 170.

Meanwhile, that the second base material 220 includes the optical function layer 170 means that the light-emitting unit 140 is located between the first base material 210 and the optical function layer 170. That is, in a manufacturing process or the like of the light-emitting device 10, the optical function layer 170 may be a layer formed on the first base material 210, or may be a layer having a portion thereof in contact with the first base material 210.

The optical function layer 170 will be described below. The optical function layer 170 is a layer which has at least any of functions of, for example, a wavelength selective optical filter, a wavelength selective absorption filter, a wavelength selective light shielding filter, and a wavelength selection type reflecting layer. That is, the optical function layer 170 need only be a layer which inhibits transmission of light of a wavelength other than those in a certain wavelength band including the first wavelength out of visible light more than transmission of light of the certain wavelength band. The certain wavelength band is in a range from, for example, equal to or more than a wavelength shorter than the first wavelength by 50 nm to equal to or less than a wavelength longer than the first wavelength by 50 nm. An example of the optical function layer 170 being a wavelength selection type reflecting layer is explained in detail below.

As long as the optical function layer 170 according to the present embodiment is a layer which particularly reflects light of the first wavelength, it is not particularly limited, but is, for example, a layer which corresponds to at least any of a first example to a fifth example. In the following, the first wavelength includes a maximum peak in the emission spectrum of the light-emitting unit 140.

Here, the emission spectrum of the light-emitting unit 140 is obtained by, for example, measuring light outputted from an output surface on a first base material 210 side of the light-emitting device 10. Further, in a case where the optical function layer 170 is formed throughout the entirety of a first region 102, a second region 104, and a third region 106, a reflection spectrum of the optical function layer 170 maybe obtained by, for example, measuring regularly reflected light when light is irradiated from a second base material 220 side to the light-emitting device 10. In addition, since the second base material 220 has light-transmitting properties, a structure including the optical function layer 170 may be cutout from the light-emitting device 10 and a reflectance of light measured from the structure maybe regarded as the reflectance of light of the optical function layer 170. For example, in the example shown in the present drawing, an adhesive layer 184 may be cut to obtain a structure including a sealing member 180, the optical function layer 170, and a portion of the adhesive layer 184, allowing the structure to be used as an object of measurement. A measuring range of the emission spectrum and the reflection spectrum is, for example, from 400 nm to 700 nm. Meanwhile, the existence of the optical function layer 170 and a wavelength of a particularly high reflectance may be checked by analyzing a cross section of the light-emitting device 10 and checking a material of a laminated film and the thickness thereof.

In the first example, the optical function layer 170 has a higher reflectance of light at the first wavelength than a mean value of reflectances of light (average reflectance) within a wavelength range of, for example, equal to or greater than 400 nm and equal to or less than 700 nm. Here, the average reflectance of the optical function layer 170 may be obtained by, for example, measuring each reflectance of the optical function layer 170 for light of a plurality of wavelengths and calculating the mean value thereof.

In a second example, at the peak including the first wavelength in the emission spectrum of the light-emitting unit 140, a wavelength range between two wavelengths each having half of an intensity of the peak intensity as upper and lower limits is set as a first range. In addition, the light reflectance of the optical function layer 170 is equal to or greater than 30% with respect to light within the first range.

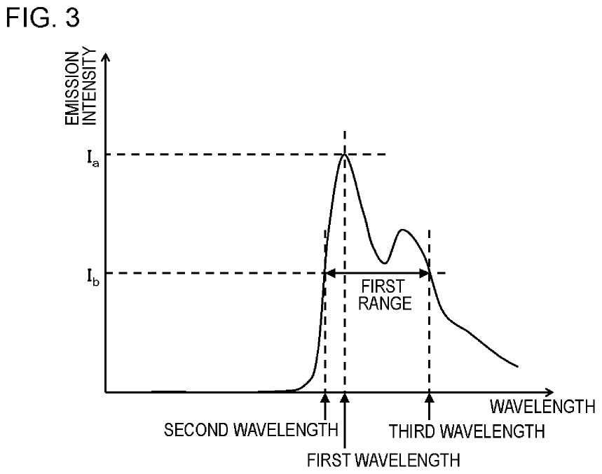

FIG. 3 is a diagram showing an example of an emission spectrum of the light-emitting unit 140. The second example will be described using the present diagram. In the emission spectrum illustrated in the present diagram, the maximum peak is included in the first wavelength. The peak intensity of the first wavelength is Iₐ. Further, in the present diagram, the intensity of an emission intensity I_{b}, is one half of Iₐ. The base of the peak of the first wavelength becomes the intensity I_{b} at a second wavelength and a third wavelength. The second wavelength is shorter than the third wavelength. Here, the wavelength range between the second wavelength as a lower limit and the third wavelength as an upper limit is the first range. Further, in the second example, the reflectance of the optical function layer 170 is equal to or greater than 30% throughout the entirety of the first range. Then, the amount of light leaked from the rear surface may seem small to the human eye. In addition, the reflectance of the optical function layer 170 is more preferably equal to or greater than 50% throughout the entirety of the first range.

Meanwhile, in a case where the emission spectrum of the light-emitting unit 140 has the above-mentioned intensity I_{b} at three or more wavelengths, out of these wavelengths, the second wavelength is set to the wavelength that is shorter than the first wavelength and the nearest to the first wavelength. Further, out of these wavelengths, the third wavelength is set to the wavelength that is longer than, and the nearest to the first wavelength. Meanwhile, in the first range, at a wavelength other than the first wavelength, another emission peak may further exist.

In a third example, the optical function layer 170 is a layer having a maximum reflectance in the first range explained in the second example. Specifically, a wavelength having a maximum reflectance in a reflection spectrum of light of the optical function layer 170 within a wavelength range of equal to or greater than 400 nm and equal to or less than 700 nm is located within the first wavelength range.

In a fourth example, a maximum reflectance in the reflection spectrum of light of the optical function layers 170 within the wavelength range of equal to or greater than 400 nm and equal to or less than 700 nm is Rₘₐₓ. Further, a wavelength range having a reflectance which is equal to or greater than Rₘₐₓ×0.5 is a second range. Further, the first wavelength is included in the second range.

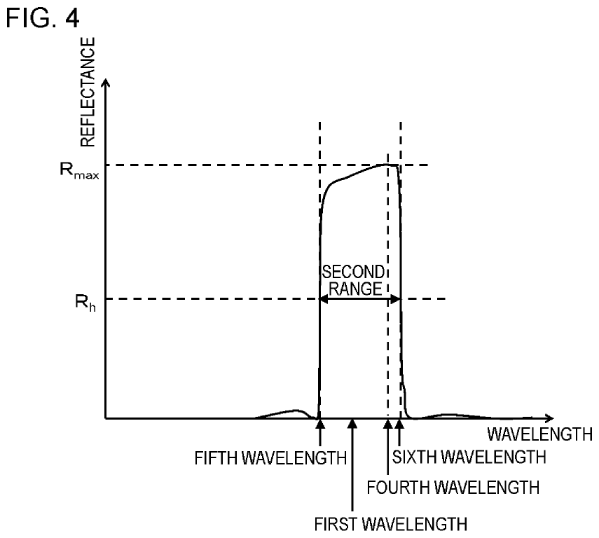

FIG. 4 is a diagram of an example of the reflection spectrum of the optical function layer 170. The fourth example will be described using the present diagram. The reflection spectrum shown in the diagram shows a maximum reflectance Rₘₐₓ at a fourth wavelength. Further, in the present diagram, the size of a reflectance Rₕ is 0.5 times that of Rₘₐₓ. In the present diagram, a fifth wavelength and a sixth wavelength show wavelengths having the reflectance Rₕ. The fourth wavelength is located between the fifth wavelength and the sixth wavelength, and the fifth wavelength is shorter than the sixth wavelength. Here, the wavelength range between the fifth wavelength as a lower limit and the sixth wavelength as an upper limit may be the second range. However, the fifth wavelength need not exist within the wavelength range of equal to or greater than 400 nm and equal to or less than 700 nm. In such a case, 400 nm is the lower limit of the second range. In addition, the sixth wavelength need not exist in the range of equal to or greater than 400 nm and equal to or less than 700 nm. In such a case, 700 nm is the upper limit of the second range. Further, in the fourth example, the first wavelength as an emission spectrum peak wavelength of the light-emitting unit 140 is included in the second range.

Meanwhile, in a case where the reflection spectrum of the optical function layers 170 is the above-mentioned reflectance Rₕ at three or more wavelengths, a wavelength out of these wavelengths that is shorter than the fourth wavelength and the nearest to the fourth wavelength is the fifth wavelength. Further, out of these wavelengths, a wavelength that is longer than, and the nearest to the fourth wavelength is the sixth wavelength.

In the fifth example, a difference between a wavelength having a maximum reflectance of the reflection spectrum of the optical function layer 170 and the first wavelength which is an emission spectrum peak wavelength of the light-emitting unit 140 is equal to or less than 100 nm. In addition, a difference between a wavelength having the maximum reflectance of the reflection spectrum of the optical function layer 170 and the first wavelength as the emission spectrum peak wavelength of the light-emitting unit 140 is preferably equal to or less than 50 nm.

Further, in the above-mentioned first example to fifth example, when a wavelength range between two wavelengths as upper and lower limits each having one fifth of the intensity of the peak intensity of the peak at the first wavelength is set as a third range, an average light transmittance of the optical function layer 170 with respect to light within the third range is preferably equal to or greater than 50% . Then, the optical function layer 170 can sufficiently transmit light, thereby securing light transmittance of the light-emitting device 10.

Meanwhile, in a case where the reflection spectrum of the optical function layer 170 has an intensity which is one fifth of the peak intensity at three or more wavelengths, out of these wavelengths, a wavelength that is shorter than the first wavelength and the nearest to the first wavelength is set to be the lower limit of a third range, and a wavelength that is longer than the first wavelength and the nearest to the first wavelength is set to be the upper limit of the third range. Meanwhile, in the third range, at a wavelength other than the first wavelength, another peak may further exist.

Further, in the above-mentioned first example to fifth example, the light reflectance of the optical function layer 170 at a wavelength shorter than the first wavelength by 100 nm and a wavelength longer than the first wavelength by 100 nm is preferably equal to or less than 50% and is more preferably equal to or less than 20%. In this case, the optical function layer 170 can sufficiently transmit light of a wavelength which is distant from the first wavelength.

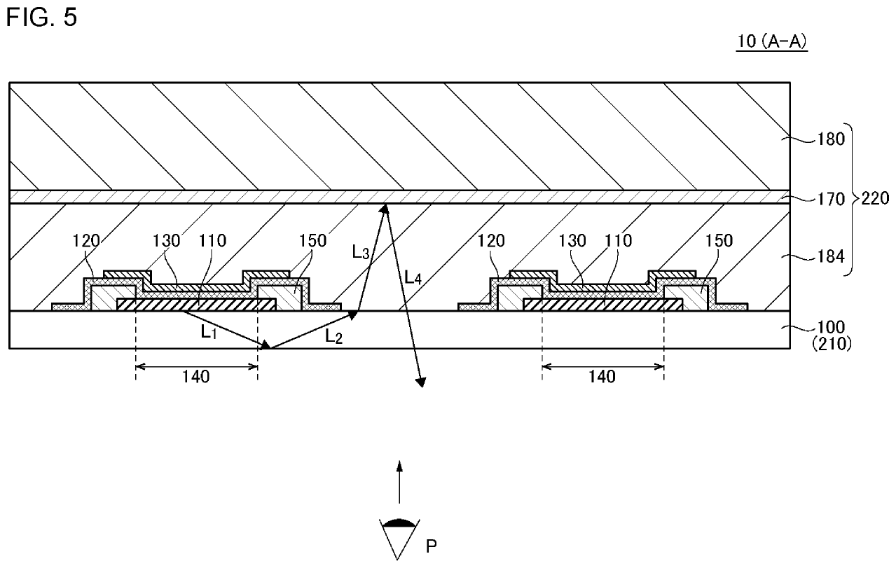

FIG. 5 is a diagram of an example of a light path in the light-emitting device 10. Hereinafter, the first base material 210 side of the light-emitting device 10 is called “a front surface”, and the second base material 220 side is called “a rear surface”. A portion of light L₁ outputted from the light-emitting unit 140 and advanced to the substrate 100 side is outputted to the outside of the light-emitting device 10. Meanwhile, a portion of light having an incident angle which is larger than a critical angle of an interface between the substrate 100 and a gas phase is totally reflected on the front surface of the light-emitting device 10 and advances in the manner of light L₂. In a case where the light L₂ is propagated through the light-emitting device 10 while maintaining its angle, the light L₂ is repeatedly totally reflected on the front surface and the rear surface of the light-emitting device 10, and is outputted from a side surface of the light-emitting device 10. Therefore, the light L₂ does not leak from the rear surface. However, in a case where there is an occurrence of diffusion inside the light-emitting device 10, the angle of light may change in the manner of, for example, L₃. Further, when light is incident on the interface between the rear surface of the light-emitting device 10 and the exterior gas phase at an incident angle which is smaller than the critical angle, the light leaks from the rear surface. With respect to such a case, the light-emitting device 10 according to the present embodiment includes an optical function layer 170. Therefore, light having a small incident angle with respect to the rear surface in the manner of the L₃ in the present diagram may be reflected inside the light-emitting device 10 and directed back to the front surface side in the manner of as light L₄. Meanwhile, the optical function layer 170 allows to secure visibility from the rear surface side to the front surface side of the light-emitting device 10 by selectively reflecting light of the first wavelength.

Referring back to FIG. 1 and FIG. 2, each configuration of the light-emitting device 10 will be described in detail. In the present embodiment, the light-emitting device 10 includes the first base material 210 having light-transmitting properties and the second base material 220 having light-transmitting properties. The second base material 220 includes the adhesive layer 184, the optical function layer 170, and a sealing member 180. The sealing member 180 covers the light-emitting unit 140 with the adhesive layer 184 interposed therebetween. In addition, in the present embodiment, the optical function layer 170 is in contact with the sealing member 180. In the example illustrated in FIG. 1 and FIG. 2, the optical function layer 170 is in contact with a surface of the sealing member 180 on the light-emitting unit 140 side. However, the optical function layer 170 may be in contact with a surface of the sealing member 180 on a side opposite to the light-emitting unit 140. Further, the optical function layer 170 may be formed on both surfaces of the sealing member 180.

The first base material 210 in the present embodiment includes the substrate 100. The substrate 100 is a light-transmitting substrate, for example, a glass substrate or a resin substrate. The substrate 100 may have flexibility. In a case where the substrate has flexibility, the thickness of the substrate 100 is, for example, equal to or greater than 10 μm and equal to or less than 1,000 μm. The substrate 100 is polygonal, for example, rectangular, or circular. In a case where the substrate 100 is a resin substrate, the substrate 100 is formed using, for example, polyethylene naphthalate (PEN), polyether sulphone (PES), polyethylene terephthalate (PET), or polyimide. In addition, in a case where the substrate 100 is a resin substrate, an inorganic barrier film of SiNₓ, SiON or the like is preferably formed on at least one surface (preferably, both surfaces) of the substrate 100 in order to prevent moisture from permeating the substrate 100. In this case, the first base material 210 includes the substrate 100 and the inorganic barrier film.

One surface of the substrate 100 has the light-emitting unit 140 formed thereon. The light-emitting unit 140 includes a light-transmitting first electrode 110, a light-shielding second electrode 130, and an organic layer 120 located between the first electrode 110 and the second electrode 130. The second electrode 130 is located on the side of the first electrode 110 opposite to the first base material 210. With such a configuration, light from the light-emitting unit 140 is outputted to the first base material 210 side. Meanwhile, a portion of light emitted from the light-emitting unit 140 may be outputted to the second base material 220 side as, for example, leaked light. However, the light outputted to the first base material 210 side has higher intensity than light emitted to the second base material 220 side.

In a case where the light-emitting device 10 is an illumination device, the plurality of light-emitting units 140 are linearly extended. On the other hand, in a case where the light-emitting device 10 is a display device, the plurality of light-emitting units 140 may be disposed to constitute a matrix or may be disposed to constitute segments or to display a predetermined shape (for example, an icon). Further, the plurality of light-emitting units 140 are formed in accordance with each pixel.

The first electrode 110 is a transparent electrode having optical transparency. A material of the transparent electrode is a material containing a metal, for example, a metal oxide formed of an indium tin oxide (ITO), an indium zinc oxide (IZO), an indium tungsten zinc oxide (IWZO), a zinc oxide (ZnO), or the like. The thickness of the first electrode 110 is, for example, equal to or greater than 10 nm and equal to or less than 500 nm. The first electrode 110 is formed by, for example, sputtering or vapor deposition. Meanwhile, the first electrode 110 may be a conductive organic material such as carbon nanotubes or PEDOT/PSS. In the drawing, a plurality of linear first electrodes 110 are formed in parallel to each other on the substrate 100, and the first electrodes 110 are neither located in the second region 104 nor in the third region 106.

The organic layer 120 includes a light-emitting layer. The organic layer 120 has a configuration in which, for example, a hole injection layer, a light-emitting layer, and an electron injection layer are laminated in this order. A hole transport layer may be formed between the hole injection layer and the light-emitting layer. In addition, an electron transport layer may be formed between the light-emitting layer and the electron injection layer. The organic layer 120 may be formed by vapor deposition. In addition, at least one layer in the organic layer 120, for example, a layer which is in contact with the first electrode 110, may be formed using a coating method such as ink jetting, printing, or spraying. Meanwhile, in this case, the remaining layers of the organic layer 120 may be formed by vapor deposition. In addition, all layers of the organic layer 120 may be formed using a coating method.

The second electrode 130 includes a metal layer composed of a metal selected from a first group including, for example, Al, Au, Ag, Pt, Mg, Sn, Zn, and In, or an alloy of metals selected from the first group. In this case, the second electrode 130 has light shielding properties. The thickness of the second electrode 130 is, for example, equal to or greater than 10 nm and equal to or less than 500 nm. The second electrode 130 is formed by, for example, sputtering or vapor deposition. In the example shown in the drawing, the light-emitting device 10 includes a plurality of linear second electrodes 130. Each second electrode 130 is provided per each of the first electrodes 110, and the width thereof is wider than that of the first electrode 110. Therefore, when viewed from a direction perpendicular to the substrate 100, the entirety of the first electrode 110 is overlapped and covered by the second electrode 130 in the width direction. In addition, the width of the first electrode 110 may be wider than that of the second electrode 130, and when viewed in the direction perpendicular to the substrate, the entirety of the second electrode 130 may be covered by the first electrode 110 in the width direction.

An edge of the first electrode 110 is covered by an insulating film 150. The insulating film 150 is formed of, for example, a photosensitive resin material such as polyimide and surrounds a portion of the first electrode 110 serving as the light emitting unit 140. An edge of the second electrode 130 in the width direction is located over the insulating film 150. In other words, when viewed from the direction perpendicular to the substrate 100, a portion of the insulating film 150 protrudes from the second electrode 130. In addition, in the example shown in the drawing, the organic layer 120 is formed over and on the side of the insulating film 150. Further, the organic layer 120 is divided in a region between the light-emitting units 140 next to each other. However, the organic layer 120 may be continuously provided across the light-emitting units 140 next to each other.

The light-emitting device 10 includes a first region 102, a second region 104, and a third region 106. When viewed from the direction perpendicular to the substrate 100, the first region 102 overlaps the second electrode 130. The second region 104 is a region which overlaps the insulating film 150, but does not overlap the second electrode 130. In the example illustrated in the present drawing, the organic layer 120 is also formed in the second region 104 . The third region 106 neither overlaps the second electrode 130 nor the insulating film 150. The light-transmitting region is composed of the second region 104 and the third region 106. That is, the light-transmitting region is a region which does not overlap the second electrode 130 when viewed from a direction perpendicular to the first base material 210. In the example shown in the drawing, no organic layer 120 is formed in at least a portion of the third region 106. Further, for example, the width of the second region 104 is narrower than that of the third region 106. In addition, the width of the third region 106 may be wider or narrower than that of the first region 102. In a case where the width of the first region 102 is 1, the width of the second region 104 is, for example, equal to or greater than 0 (or more than 0) and equal to or less than 0.3, and the width of the third region 106 is, for example, equal to or greater than 0.3 and equal to or less than 5. Further, the width of the first region 102 is, for example, equal to or greater than 50 μm and equal to or less than 500 μm, the width of the second region 104 is, for example, equal to or greater than 0 μm (or more than 0 μm) and equal to or less than 100 μm, and the width of the third region 106 is, for example, equal to or greater than 15 μm and equal to or less than 1,500 μm.

The planar shape of the substrate 100 is polygonal such as, for example, rectangular or the like, or circular. The sealing member 180 is light-transmitting and is formed using, for example, glass ora resin. Similarly to the substrate 100, the sealing member 180 has a polygonal or a circular shape, and has a concave portion at the center. In addition, each of the plurality of light-emitting units 140 is located inside the sealed space between the substrate 100 and the sealing member 180. An adhesive is filled in the sealed space, and the adhesive layer 184 is formed. In addition, the sealing member 180 may have a plate-like shape. In this case also, the sealing member 180 is fixed to the light-emitting unit 140 with the adhesive layer 184. As the adhesive layer 184, for example, an epoxy resin may be used.

In addition, in the present embodiment, the optical function layer 170 is formed on one surface of the sealing member 180. In the example shown in FIG. 1 and FIG. 2, the optical function layer 170 is located between the adhesive layer 184 and the sealing member 180, and is in contact with the adhesive layer 184 and the sealing member 180. However, the sealing member 180 may have the optical function layer 170 formed on at least one surface thereof. That is, the optical function layer 170 may be formed on both surfaces of the sealing member 180, or the optical function layer 170 may be provided only on a surface of the sealing member 180 on a side opposite to the light-emitting unit 140.

In the example shown in the diagram, the optical function layer 170 is formed in a region overlapping the light-transmitting region when viewed from a direction perpendicular to the first base material 210. In detail, the optical function layer 170 is formed in a region which overlaps the entirety of the light-transmitting region. Therefore, light from the light-emitting unit 140 is inhibited from being reflected and transmitted through the light-transmitting region, thereby more efficiently decreasing light leaked from the rear surface. Further, in the example shown in the diagram, the optical function layer 170 is also formed in a region overlapping the light-emitting unit 140 when viewed from a direction perpendicular to the first base material 210, and is provided to overlap the entirety of the first region 102, the second region 104, and the third region 106. Therefore, it is not necessary to conduct patterning on the optical function layer 170, and the optical function layer 170 may be formed easily. In addition, the optical function layer 170 may be provided only in a region which overlaps a light-emitting region.

The optical function layer 170 is composed of a laminated film in which a plurality of dielectric films are laminated, or a metal film. In a case where the optical function layer 170 is composed of a metal film, the optical function layer 170 is a film composed of a metal such as Al, Ag, or the like, and the thickness thereof is, for example, equal to or greater than 1 nm and equal to or less than 30 nm. Then, film formation may be stably achieved, and sufficient light transmittance may be secured. In this case, the optical function layer 170 can be formed by, for example, vapor deposition or sputtering. Ina case where the optical function layer 170 is composed of a metal film, a surface of the optical function layer 170 is covered with, for example, members having insulating properties such as the sealing member 180 and the adhesive layer 184, and is in an electrically floating state. Moreover, the optical function layer 170 is a layer which does not configure the light-emitting unit 140.

In a case where the optical function layer 170 is composed of a laminated film of a plurality of dielectric films, the laminated film is, for example, a film including an inorganic material, and configures a dielectric mirror or an interference filter. A dielectric film is, for example, a silicon oxide film, a silicon nitride film, a silicon oxynitride film, a titanium oxide film, an aluminum oxide film, and a mixed phase film of these films. In addition, the laminated film includes plural kinds of dielectric films having dielectric constants different from each other. The number of layers of the dielectric films which are included in the laminated film is not particularly limited, but is preferably equal to or greater than three. The thickness of each dielectric film is, for example, equal to or greater than 50 nm and equal to or less than 1 μm. In more detail, when the first wavelength is A and a refractive index of the dielectric film is n, the thickness of each dielectric film included in the laminated film is, for example, equal to or greater than λ/(4×n)×0.80 and equal to or less than λ/(4×n)×1.20. In this manner, light of a wavelength A can be selectively reflected. The thickness of the laminated film as the optical function layer 170 is not particularly limited, but is, for example, equal to or greater than 100 nm and equal to or less than 5 μm.

Each dielectric film can be formed by a vacuum deposition method, for example, sputtering, CVD, or ALD.

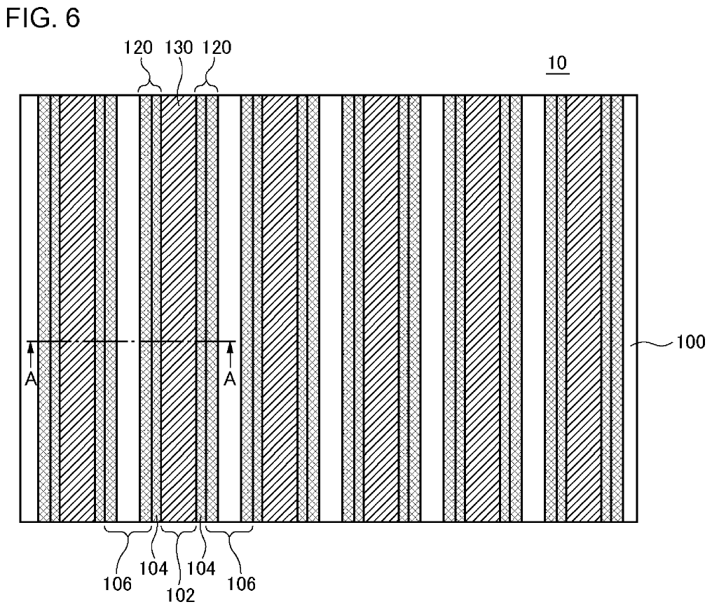

FIG. 6 is a plan view of the light-emitting device 10. However, some members are not shown in the present diagram. Meanwhile, FIG. 1 corresponds to a cross-section taken along line A-A of FIG. 6. In the example shown in the present drawing, each of the first region 102, the second region 104, and the third region 106 linearly extends in the same direction as each other. In addition, as illustrated in FIG. 6 and FIG. 1, the second region 104, the first region 102, the second region 104, and the third region 106 are repeatedly aligned in this order.

In the example shown in the present drawing, among the first region 102, the second region 104, and the third region 106, the first region 102 has the lowest light transmittance. Further, the light transmittance of the second region 104 is lower than that of the third region 106 due to the second region 104 including the insulating layer 150. In the present embodiment, for example, it is possible to make the width of the second region 104 narrower than that of the third region 106. Then, in the light-emitting device 10, an area occupying ratio of the second region 104 is lower than that of the third region 106, and the light transmittance of the light-emitting device 10 becomes higher.

Next, a method of manufacturing the light-emitting device 10 will be described. First, the first electrode 110 is formed on the substrate 100 by, for example, sputtering. Then, the first electrode 110 is formed in a predetermined pattern by, for example, photolithography. The insulating layer 150 is then formed over an edge of the first electrode 110. For example, in a case where the insulating layer 150 is formed of a photosensitive resin, the insulating layer 150 is formed in a predetermined pattern by undergoing exposure and development steps. Next, the organic layer 120 and the second electrode 130 are formed in this order. Ina case where the organic layer 120 includes a layer formed by vapor deposition, this layer is formed in a predetermined pattern using, for example, a mask or the like. The second electrode 130 is also formed in a predetermined pattern using, for example, a mask. Next, the sealing member 180 having the optical function layer 170 formed thereon is adhered with the adhesive layer 184 to seal the light-emitting unit 140.

As stated above, in the present embodiment, the light-emitting device 10 includes a light-emitting region located between the plurality of light-emitting units 140. In addition, the second base material 220 includes an optical function layer 170 which corresponds to at least any of the above-mentioned first example to fifth example. Therefore, light reflected on the front surface side of the substrate 100 is inhibited from being emitted to the rear surface side of the light-emitting device 10, thereby reducing light leaked from the rear surface.

### Second Embodiment

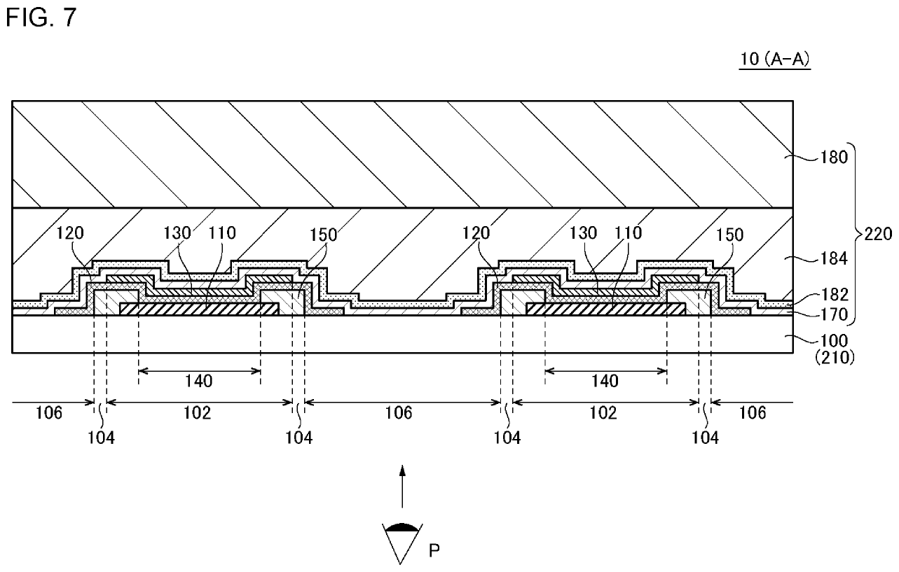

FIG. 7 is a cross-sectional view of a configuration of a light-emitting device 10 according to a second embodiment. The present drawing corresponds to FIG. 1 in the first embodiment. The light-emitting device 10 according to the present embodiment is the same as the light-emitting device 10 according to the first embodiment except a point described below.

In the present embodiment, the optical function layer 170 is formed between the light-emitting unit 140 and the adhesive layer 184. Particularly, in the example shown in FIG. 7, the optical function layer 170 is in contact with the light-emitting unit 140. Therefore, it is possible to reflect light advancing from the front surface of the light-emitting device 10 on the rear surface thereof before being incident on the adhesive layer 184 and the sealing member 180. As a result, the frequency of the occurrence of diffused light becoming light leaked from the rear surface, that is, the occurrence of light having a small incident angle with respect to the interface between the rear surface of the light-emitting device 10 and the gas phase, may be decreased.

In the example shown in the drawing, the light-emitting device 10 includes a sealing film 182. The sealing film 182 is formed to cover the light-emitting unit 140. In the example shown in the present drawing, the sealing film 182 is in contact with the optical function layer 170, and when viewed from the direction perpendicular to the substrate 100, the sealing film 182 covers the entirety of the first region 102, the second region 104, and the third region 106. However, the sealing film 182 need not be formed in at least a portion of the light-transmitting region.

An inorganic barrier film such as, for example, SiNₓ, SiON, Al₂O₃, and Tio₂, or a barrier laminated film including these, or a mixed film of these may be used as the sealing film 182. These can be formed by a vacuum deposition method, for example, sputtering, CVD, and ALD.

In the method for manufacturing the light-emitting device 10 in the present embodiment, steps up to the formation of the light-emitting unit 140 may be performed similarly to the first embodiment. In the present embodiment, next, the optical function layer 170 and the sealing film 182 are formed on the second electrode 130. Then, the sealing member 180 is adhered with the adhesive layer 184, and the light-emitting unit 140 is sealed via the optical function layer 170 and the sealing film 182.

Meanwhile, in the example shown in the drawing, the optical function layer 170 and the sealing film 182 are laminated in this order from the light-emitting unit 140 side, and the optical function layer 170 is in contact with the light-emitting unit 140, but the laminating order of the sealing film 182 and the optical function layer 170 maybe reversed. That is, the sealing film 182 and the optical function layer 170 may be laminated in this order from the light-emitting unit 140 side, and the sealing film 182 maybe in contact with the light-emitting unit 140. However, when the optical function layer 170 is a metal film, the sealing film 182 is made to be located between the optical function layer 170 and the second electrode 130 so that the optical function layer 170 and the second electrode 130 are not in contact with each other. By the above structure, the second electrodes 130 of the plurality of light-emitting units 140 are prevented from short-circuiting.

Further, the sealing film 182 may also function as the optical function layer 170. That is, the second base material 220 includes the sealing film 182 which covers the light-emitting unit 140 and is in contact therewith, and this sealing film 182 may be the optical function layer 170. In this case, in manufacturing the light-emitting device 10, it is possible to reduce the number of steps of film formation.

Further, in the configuration of the present embodiment, similarly to the first embodiment, the optical function layer 170 may be provided on at least one surface of the sealing member 180.

In addition, in the present embodiment, both the sealing film 182 and the sealing member 180 do not necessarily need to be provided in the light-emitting device 10, but it is sufficient if at least one of them is provided. Then, the light-emitting unit 140 is sealed, thereby securing durability of the light-emitting unit 140. In addition, when the light-emitting device 10 does not include the sealing member 180, the adhesive layer 184 does not necessarily need to be formed on the light-emitting device 10.

As stated above, in the present embodiment also, the light-emitting device 10 includes the light-emitting region located between the plurality of light-emitting units 140. In addition, the second base material 220 includes the optical function layer 170 which corresponds to at least any of the optical function layers described in the above-mentioned first example to fifth example. Therefore, light reflected on the front surface side of the substrate 100 is inhibited from being emitted to the rear surface side of the light-emitting device 10, thereby reducing the light leaked from the rear surface.

### Third Embodiment

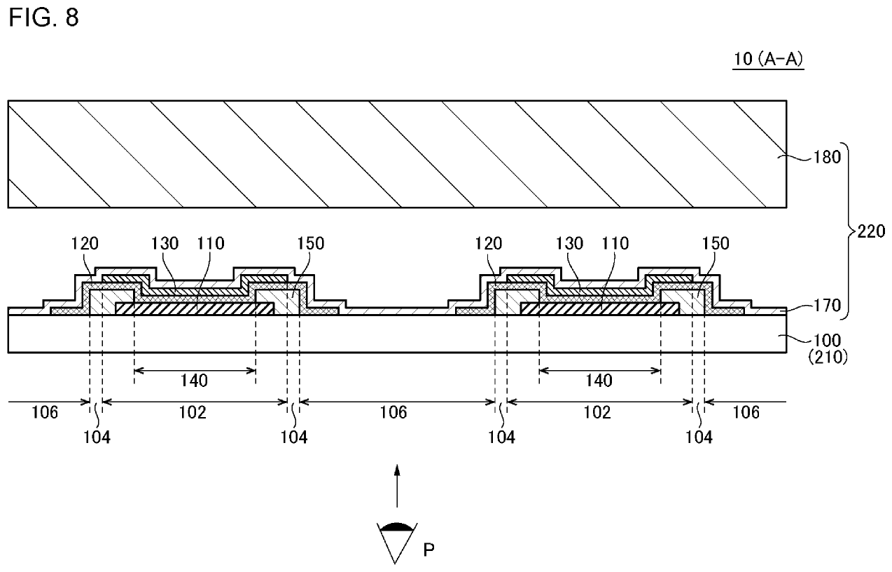

FIG. 8 is a cross-sectional view of a configuration of a light-emitting device 10 according to a third embodiment. The present drawing corresponds to FIG. 1 in the first embodiment. The light-emitting device 10 according to the present embodiment is the same as at least one of the light-emitting devices 10 according to the first and second embodiments, except for points described below.

In the present embodiment, the sealing member 180 is fixed only on the edges to substrate 100. Therefore, the first region 102, the second region 104, and the third region 106 are not covered with the adhesive layer 184. Then, a gas phase exists between a light-emitting unit 140 and the sealing member 180.

In a method for manufacturing the light-emitting device 10 in the present embodiment, steps up to the formation of an optical function layer 170 may be performed similarly to the second embodiment. In the present embodiment, next, the light-emitting unit 140 is covered with the sealing member 180, and the edges of the sealing member 180 is fixed to the substrate 100 with an adhesive. With such a step, the light-emitting unit 140 is sealed in a space between the sealing member 180 and the substrate 100.

Meanwhile, in the example shown in the present drawing, the optical function layer 170 is in contact with the light-emitting unit 140. However, similarly to the first embodiment, the optical function layer 170 may be provided on at least one surface of the sealing member 180.

In addition, the light-emitting device 10 may further include the sealing film 182 as shown in the second embodiment.

As stated above, in the present embodiment also, the light-emitting device 10 includes a light-transmitting region located between the plurality of light-emitting units 140. Then, the second base material 220 includes an optical function layer 170 which corresponds to at least any of the optical function layers 170 described in the above-mentioned first example to fifth example. Therefore, light reflected on the front surface side of the substrate 100 is inhibited from being emitted to the rear surface side of the light-emitting device 10, thereby reducing light leaked from the rear surface.

### Fourth Embodiment

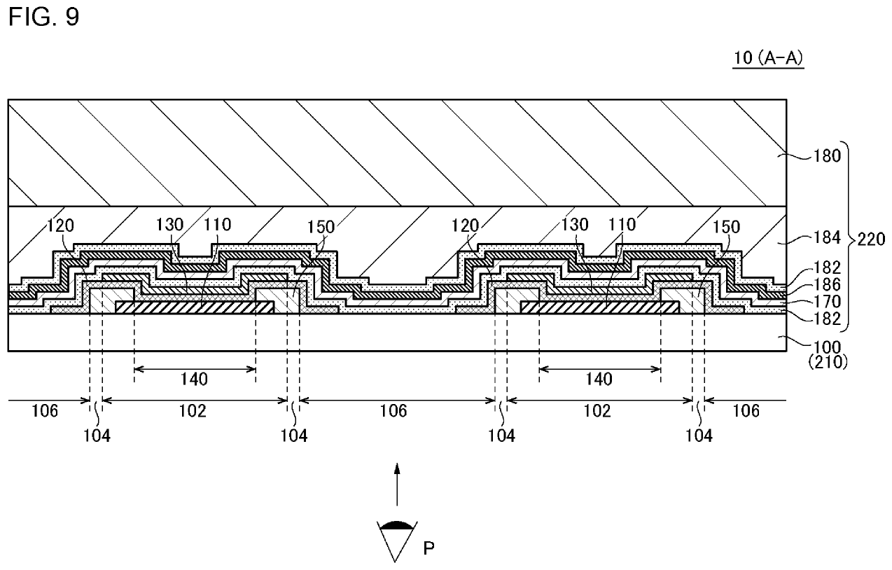

FIG. 9 is a cross-sectional view of a configuration of a light-emitting device 10 according a fourth embodiment. The present drawing corresponds to FIG. 1 in the first embodiment. The light-emitting device 10 according to the present embodiment is the same as the light-emitting device 10 according to at least any of the first to third embodiments, except that a plurality of sealing films 182 are included.

In the example shown in the present drawing, a sealing film 182, the optical function layer 170, the resin layer 186, and a sealing film 182 are laminated in this order from the light-emitting unit 140 side. However, it is not limited to the example shown in the present drawing, for example, the optical function layer 170, a sealing film 182, the resin layer 186, and a sealing film 182 may be laminated in this order from the light-emitting unit 140 side. The resin layer 186 is composed of, for example, a resin such as a polyimide, an epoxy resin, and an acrylic resin or the like, or a coating type inorganic material such as polysilazane or the like. Meanwhile, the present drawing shows an example of two layers of the sealing films 182 being included in the light-emitting device 10. However, the light-emitting device 10 may include three or more layers of the sealing films 182. Even in such a case, the resin layer 186 is provided between two sealing films 182. Further, the light-emitting device 10 may include two or more layers of the optical function layers 170 between the light-emitting unit 140 and the adhesive layer 184.

In a method for manufacturing the light-emitting device 10 in the present embodiment, steps up to the formation of the light-emitting unit 140 may be performed similarly to the first embodiment. In the present embodiment, next, a sealing film 182, the optical function layer 170, the resin layer 186, and a sealing film 182 are laminated in this order on the second electrode 130. Here, the resin layer 186 may be formed by a coating method such as, for example, spin coating, ink jetting, or the like. Then, the sealing member 180 is adhered with the adhesive layer 184, and the light-emitting unit 140 is sealed via the optical function layer 170 and the sealing film 182 or the like.

Meanwhile, as is the case with first embodiment, the optical function layer 170 maybe further provided on at least one of the sealing members 180. In addition, the light-emitting device 10 need not include neither the sealing member 180 nor the adhesive layer 184.

As stated above, in the present embodiment also, the light-emitting device 10 includes a light-transmitting region located between the plurality of light-emitting units 140. In addition, the second base material 220 includes an optical function layer 170 which corresponds to at least any of the optical function layers described in the above-mentioned first example to fifth example. Therefore, light reflected on the front surface side of the substrate 100 is inhibited from being emitted to the rear surface side of the light-emitting device 10, thereby reducing light leaked from the rear surface.

In addition, the light-emitting device 10 in the present embodiment includes the plurality of sealing films 182. Therefore, the light-emitting unit 140 may be sealed more firmly, thereby increasing durability of the light-emitting unit 140.

### Fifth Embodiment

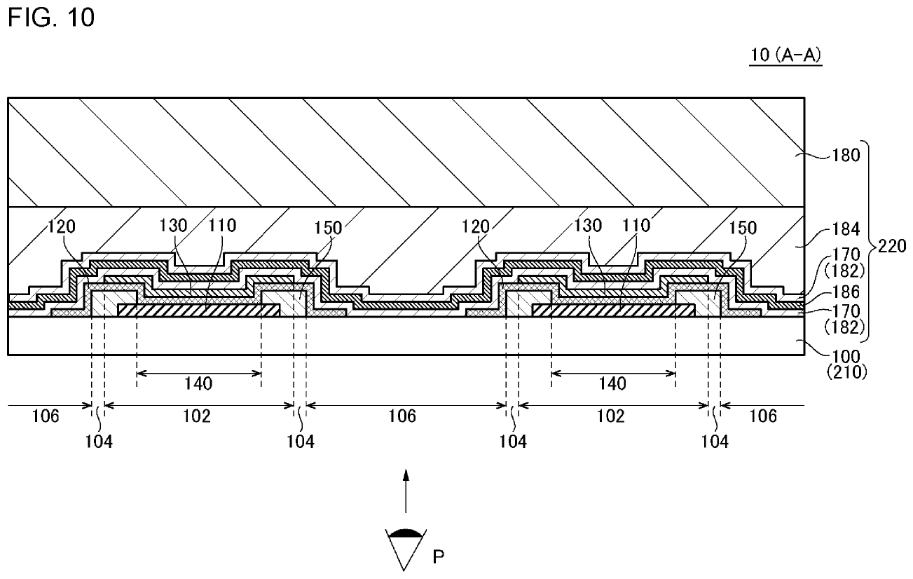

FIG. 10 is a cross-sectional view of a configuration of a light-emitting device 10 according to a fifth embodiment. The present drawing corresponds to FIG. 1 in the first embodiment. The light-emitting device 10 according to the present embodiment is the same as the light-emitting device 10 according to the fourth embodiment, except that the sealing film 182 also functions as the optical function layer 170.

In the present embodiment, the sealing film 182 is a laminated film having a plurality of laminated inorganic films such as, for example, SiNₓ, SiON, Al₂O₃, and Tio₂ and has barrier properties. In addition, the sealing film 182 also is a laminated film of a plurality of dielectric films as described in the first embodiment, and functions as the optical function layer 170. Each of the inorganic films can be formed by a vacuum deposition method, such as for example, sputtering, CVD, and ALD. In the present embodiment, the thickness of the optical function layer 170 is preferably equal to or greater than 100 nm and equal to or less than 5 μm.

In a method for manufacturing the light-emitting device 10 in the present embodiment, steps up to the formation of the light-emitting unit 140 may be performed similarly to the first embodiment. In the present embodiment, next, the optical function layer 170, the resin layer 186, and the optical function layer 170 are laminated in this order on the second electrode 130. Here, the resin layer 186 may be formed by a coating method such as, for example, spin coating, ink jetting, or the like. Then, the sealing member 180 is adhered with the adhesive layer 184, and the light-emitting unit 140 is sealed via the optical function layer 170 and the resin layer 186 or the like.

As stated above, in the present embodiment also, the light-emitting device 10 includes a light-transmitting region located between the plurality of light-emitting units 140. In addition, the second base material 220 includes an optical function layer 170 which corresponds to at least any of the optical function layers described in the above-mentioned first example to fifth example. Therefore, light reflected on the front surface side of the substrate 100 is inhibited from being emitted to the rear surface side of the light-emitting device 10, thereby reducing light leaked from the rear surface.

In addition, the light-emitting device 10 in the present embodiment includes a plurality of sealing films 182. Therefore, the light-emitting unit 140 may be sealed more firmly, thereby increasing durability of the light-emitting unit 140.

Further, the sealing film 182 also functions as the optical function layer 170. Therefore, in manufacturing the light-emitting device 10, it is possible to reduce the number of steps of film formation.

### Sixth Embodiment

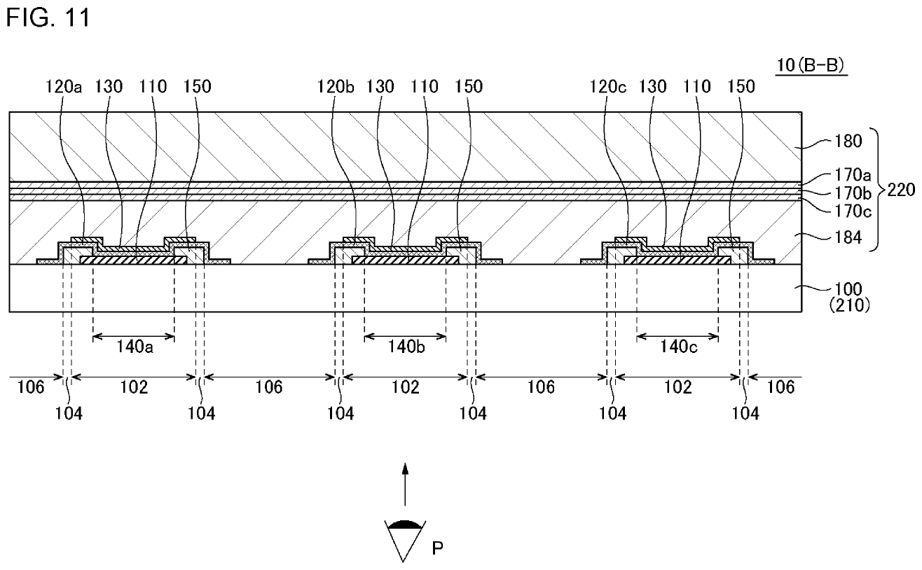

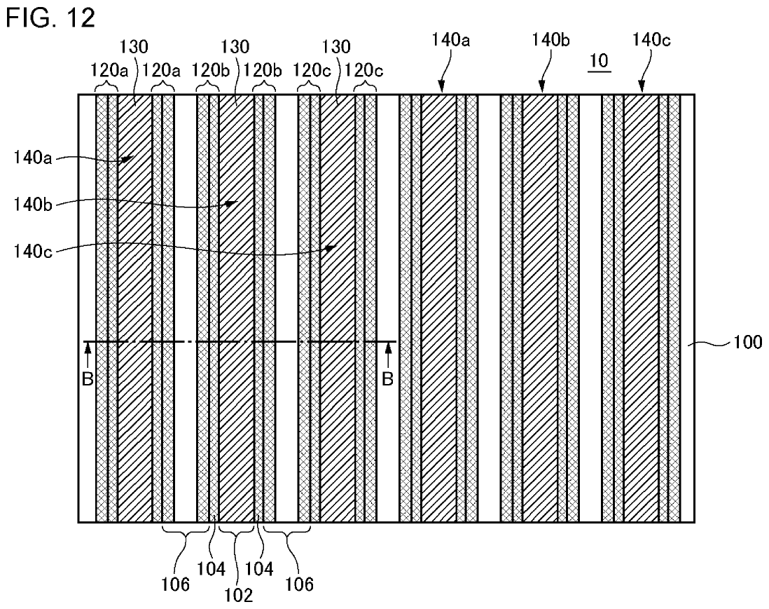

FIG. 11 is a cross-sectional view of a configuration of a light-emitting device 10 according to a sixth embodiment. The present drawing corresponds to FIG. 1 in the first embodiment. FIG. 12 is a plan view of the light-emitting device 10 according to the sixth embodiment. However, some members are not shown in the present diagram. Meanwhile, FIG. 11 corresponds to a cross-section taken along line B-B of FIG. 11. The light-emitting device 10 according to the present embodiment is the same as the light-emitting device 10 according to at least any of first to fifth embodiments, except for points described below.

The light-emitting device 10 in the present embodiment includes a first light-emitting unit 140a, and a second light-emitting unit 140b having a first wavelength different from that of the first light-emitting unit 140a. In an example illustrated in FIG. 11 and FIG. 12, the light-emitting device 10 includes the first light-emitting unit 140a, the second light-emitting unit 140b, and a third light-emitting unit 140c as the light-emitting units 140. The first light-emitting unit 140a includes a first organic layer 120a, the second light-emitting unit 140b includes a second organic layer 120b, and the third light-emitting unit 140c includes a third organic layer 120c. Each emission color of the first light-emitting unit 140a, the second light-emitting unit 140b, and the third light-emitting unit 140c is different from each other, that is, each first wavelength is different from the other.

For example, the emission spectrum peak wavelength of the first light-emitting unit 140a (the first wavelength of the first light-emitting unit 140a) is longer than the emission spectrum peak wavelength of the second light-emitting unit 140b (the first wavelength of the second light-emitting unit 140b). In addition, the emission spectrum peak wavelength of the second light-emitting unit 140b is longer than the emission spectrum peak wavelength of the third light-emitting unit 140c (the first wavelength of the third light-emitting unit 140c). The emission color of the first light-emitting unit 140a is, for example, red, and the first wavelength of the first light-emitting unit 140a is, for example, equal to or greater than 600 nm and equal to or less than 650 nm. The emission color of the second light-emitting unit 140b is, for example, green, and the first wavelength of the second light-emitting unit 140b is, for example, equal to or greater than 500 nm and equal to or less than 580 nm. The emission color of the third light-emitting unit 140c is, for example, blue, and the first wavelength of the third light-emitting unit 140c is, for example, equal to or greater than 430 nm and equal to or less than 470 nm.

In addition, as illustrated in FIG. 11 and FIG. 12, the first light-emitting unit 140a, the second light-emitting unit 140b, and the third light-emitting unit 140c are repeatedly aligned in order.

As such, since the light-emitting device 10 includes the first light-emitting unit 140a, the second light-emitting unit 140b, and the third light-emitting unit 140c which generate the emission colors different from each other, the light-emitting device 10 may be used as white illumination or color illumination. Further, the color of the entire light-emitting device 10 may be adjusted by independently adjusting each light emission of the first light-emitting unit 140a, the second light-emitting unit 140b, and the third light-emitting unit 140c.

The second base material 220 according to the present embodiment includes a first optical function layer 170a, a second optical function layer 170b, and a third optical function layer 170c as the optical function layer 170. The first optical function layer 170a is a layer that particularly reflects light of the first wavelength of the first light-emitting unit 140a, the second optical function layer 170b is a layer that particularly reflects light of the first wavelength of the second light-emitting unit 140b, and the third optical function layer 170c is a layer that particularly reflects light of the first wavelength of the third light-emitting unit 140c. Each of a relationship between the first the optical function layer 170a and the first wavelength of the first light-emitting unit 140a, a relationship between the second optical function layer 170b and the first wavelength of the second light-emitting unit 140b, and a relationship between the third optical function layer 170c and the first wavelength of the third light-emitting unit 140c corresponds to at least any of the relationships between the optical function layer 170 and the first wavelength of the light-emitting unit 140 in the first example to the fifth example explained in the first embodiment. For example, in a case where each of the optical function layer 170a, the second optical function layer 170b, and the third optical function layer 170c is composed of a laminated film of a plurality of dielectric films, at least one of the film thickness and a material of the plurality of dielectric films which compose the optical function layer 170a, the second optical function layer 170b, and the third optical function layer 170c is different from each other.

A laminate of the first optical function layer 170a, the second optical function layer 170b, and the third optical function layer 170c particularly reflects the first wavelength of the first light-emitting unit 140a, the second light-emitting unit 140b, and the third light-emitting unit 140c. Meanwhile, the laminate as a whole has optical transparency. Therefore, it is possible to secure visibility from the front surface side to the rear surface side and from the rear surface side to the front surface side of the light-emitting device 10.

In the example illustrated in FIG. 11, the first optical function layer 170a, the second optical function layer 170b, and the third optical function layer 170c are laminated in this order. However, the laminating order of the first optical function layer 170a, the second optical function layer 170b, and the third optical function layer 170c is not particularly limited. In addition, in the example shown in the present drawing, the first optical function layer 170a, the second optical function layer 170b, and the third optical function layer 170c are provided in contact with each other. However, another layer may be provided between the first optical function layer 170a, the second optical function layer 170b, and the third optical function layer 170c.

In addition, in the example shown in FIG. 11, when viewed from a direction perpendicular to the first base material 210, the first optical function layer 170a, the second optical function layer 170b, and the third optical function layer 170c are provided to overlap the entirety of the first region 102, the second region 104, and a third region 106. Therefore, it is not necessary to conduct patterning on any of the first optical function layer 170a, the second optical function layer 170b, or the third optical function layer 170c, and the optical function layer 170 may be easily formed. However, the first optical function layer 170a, the second optical function layer 170b, and the third optical function layer 170c need only be formed in at least a portion of a region which overlaps the light-transmitting region.

Meanwhile, the light-emitting device 10 may have, instead of three layers of the first optical function layer 170a, the second optical function layer 170b, and the third optical function layer 170c, one optical function layer 170 which satisfies at least any of the relationships of the first example to the third example with respect to all of the first light-emitting unit 140a, the second light-emitting unit 140b, and the third light-emitting unit 140c. Thereby, it is possible to reduce the number of steps of layer formation in manufacturing the light-emitting device 10.

As stated above, in the present embodiment also, the light-emitting device 10 includes a light-transmitting region located between the plurality of light-emitting units 140. In addition, the second base material 220 includes an optical function layer 170 which corresponds to at least any of the above-mentioned first example to fifth example. Therefore, light reflected on the front surface side of the substrate 100 is inhibited from being emitted to the rear surface side of the light-emitting device 10, thereby reducing light leaked from the rear surface.

In addition, the light-emitting device 10 in the present embodiment includes at least the first light-emitting unit 140a, and the second light-emitting unit 140b having a first wavelength different from that of the first light-emitting unit 140a. Therefore, the color of the entire light-emitting device 10 may be adjusted.

### Seventh Embodiment

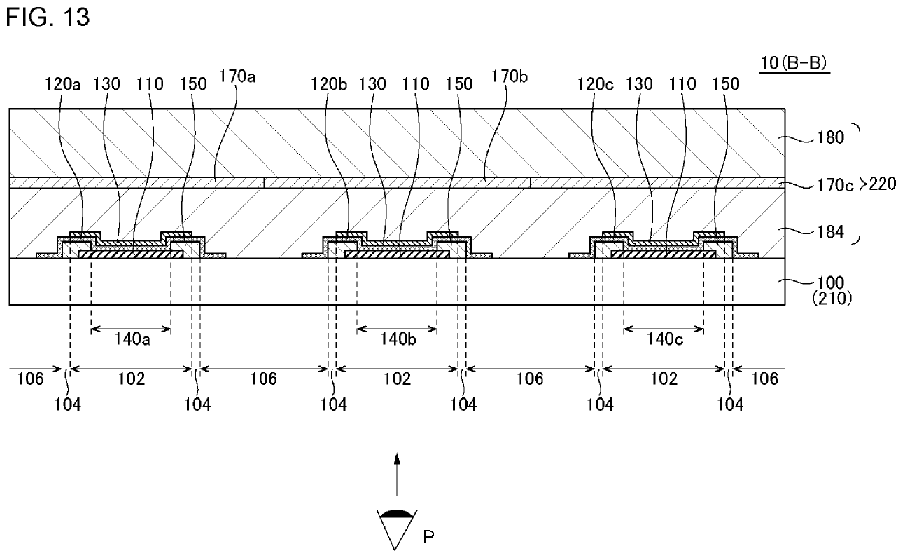

FIG. 13 is a cross-sectional view of a configuration of a light-emitting device 10 according to a seventh embodiment. The present drawing corresponds to FIG. 1 in the first embodiment. The light-emitting device 10 according to the present embodiment is the same as the light-emitting device 10 in the sixth embodiment, except for points described below.

The second base material 220 in the light-emitting device 10 in the present embodiment includes a first optical function layer 170a, a second optical function layer 170b, and a third optical function layer 170c. Each of the first optical function layer 170a, the second optical function layer 170b, and the third optical function layer 170c extends linearly in the same direction as each other and are repeatedly aligned.

When viewed from a direction perpendicular to the first base material 210, the first optical function layer 170a overlaps the first light-emitting unit 140a, the second optical function layer 170b overlaps the second light-emitting unit 140b, and the third optical function layer 170c overlaps the third light-emitting unit 140c. Further, respective ones of the first optical function layer 170a, the second optical function layer 170b, and the third optical function layer 170c protrude from respective regions which overlap the first light-emitting unit 140a, the second light-emitting unit 140b, and the third light-emitting unit 140c and overlap with at least a portion of respective light-transmitting regions adjacent to the first light-emitting unit 140a, the second light-emitting unit 140b, and the third light-emitting unit 140c. In the present drawing, an example of the first optical function layer 170a, the second optical function layer 170b, and the third optical function layer 170c being in contact with each other at the edges thereof is illustrated, but it is not limited thereto. The first optical function layer 170a, the second optical function layer 170b, and the third optical function layer 170c may be separated from each other or edges thereof may be overlapped with each other.

Each of the first optical function layer 170a, the second optical function layer 170b, and the third optical function layer 170c according to the present embodiment may be formed by patterning using lithography or a masking method.

As stated above, in the present embodiment, the light-emitting device 10 includes a light-emitting region located between the plurality of light-emitting units 140. In addition, the second base material 220 includes an optical function layer 170 which corresponds to at least any of the optical function layers 170 described in the above-mentioned first example to fifth example. Therefore, light reflected on the front surface side of the substrate 100 is inhibited from being emitted to the rear surface side of the light-emitting device 10, thereby reducing light leaked from the rear surface.

In addition, the light-emitting device 10 in the present embodiment includes at least the first light-emitting unit 140a, and the second light-emitting unit 140b having a first wavelength different from that of the first light-emitting unit 140a. Therefore, the color of the entire light-emitting device 10 may be adjusted.

In addition, in the light-emitting device 10 of the present embodiment, a plurality of optical function layers 170 having wavelengths that particularly reflect that are different from each other are provided aligned in a direction parallel to the first base material 210. Therefore, it is possible to secure high optical transparency of the light-emitting device 10.

### EXAMPLE 1

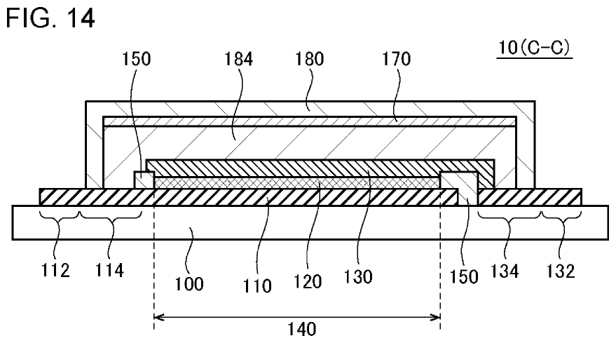

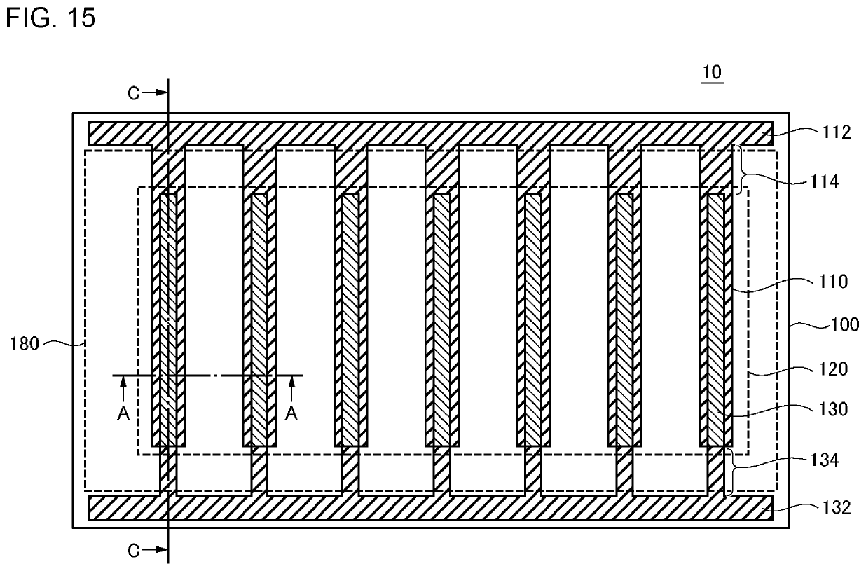

FIG. 14 is a cross-sectional view of a configuration of a light-emitting device 10 according to Example 1. FIG. 15 is a plan view of the light-emitting device 10 illustrated in FIG. 14. However, some members are not illustrated in FIG. 15. FIG. 14 corresponds to a cross-section taken along line C-C of FIG. 15. The light-emitting device 10 according to the present example includes the same configuration as that of the light-emitting device 10 according to at least any of the first to seventh embodiments. Meanwhile, an example of the light-emitting device 10 including a configuration of the first embodiment is illustrated in FIG. 14 and FIG. 15. FIG. 1 corresponds to a cross-sectional view taken along line A-A of FIG. 15.

Further, the light-emitting device 10 includes a first terminal 112, a first lead-out wiring 114, a second terminal 132, and a second lead-out wiring 134. Each of the first terminal 112, the first lead-out wiring 114, the second terminal 132, and the second lead-out wiring 134 is formed on the same surface as the surface of the substrate 100 on which the light-emitting unit 140 is formed. The first terminal 112 and the second terminal 132 are located outside the sealing member 180. The first lead-out wiring 114 connects the first terminal 112 to the first electrode 110, and the second lead-out wiring 134 connects the second terminal 132 to the second electrode 130. In other words, both the first lead-out wiring 114 and the second lead-out wiring 134 extend from the inside to the outside of the sealing member 180.

The first terminal 112, the second terminal 132, the first lead-out wiring 114, and the second lead-out wiring 134 have, for example, a layer formed of the same material as that of the first electrode 110. Further, at least a portion of at least one of the first terminal 112, the second terminal 132, the first lead-out wiring 114, and the second lead-out wiring 134 may include thereon a metal film having a lower resistance than the first electrode 110. This metal film has, for example, a configuration in which a first metal layer of Mo, a Mo alloy, or the like, a second metal layer of Al, an Al alloy, or the like, and a third metal layer of Mo, a Mo alloy, or the like are laminated in this order. It is not necessary that the metal film is formed on each of the first terminal 112, the second terminal 132, the first lead-out wiring 114, and the second lead-out wiring 134.

A layer formed of the same material as that of the first electrode 110 among the first terminal 112, the first lead-out wiring 114, the second terminal 132, and the second lead-out wiring 134 is formed in the same step as that of forming the first electrode 110. Therefore, the first electrode 110 is formed integrally with at least a portion of the layer of the first terminal 112. In addition, in a case where these include a metal film, this metal film is formed by, for example, film formation by sputtering or the like and patterning by etching or the like. In this case, light transmittance of the first terminal 112, the first extraction interconnect 114, the second terminal 132, and the second extraction interconnect 134 is lower than that of the substrate 100.

In the example shown in the drawing, one first lead-out wiring 114 and one second lead-out wiring 134 are formed for each light-emitting unit 140. Each of the plurality of first lead-out wirings 114 is connected to the same first terminal 112, and each of the plurality of second lead-out wirings 134 is connected to the same second terminal 132. A positive electrode terminal of a control circuit is connected to the first terminal 112 via a conductive member such as a bonding wire, a lead terminal, or the like, and a negative electrode terminal of the control circuit is connected to the second terminal 132 via a conductive member such as a bonding wire, a lead terminal, or the like. However, in a case where the light-emitting device 10 includes a configuration in the sixth or the seventh embodiment, the light-emitting device 10 may include a plurality of second terminals 132, and the second lead-out wirings 134 may be connected to respective second terminals 132 which are different from each other.

As stated above, in the present example also, the light-emitting device 10 includes a light-transmitting region located between the plurality of light-emitting units 140. In addition, the second base material 220 includes an optical function layer 170 which corresponds to at least any of the optical function layers described in the above-mentioned first example to fifth example. Therefore, light reflected on the front surface side of the substrate 100 is inhibited from being emitted to the rear surface side of the light-emitting device 10, thereby reducing light leaked from the rear surface.

An example of a bottom-emission type light-emitting device has been shown in the above-mentioned embodiments and example. However, the light-emitting device is not limited thereto. For example, the light-emitting device may be a top-emission type.

In addition, in each of the embodiments and the example mentioned above, the light-emitting device 10 need not include the sealing member 180. In such a case, the light-emitting device 10 is located between the first base material 210 having light-transmitting properties and the covering layer having light-transmitting properties, and includes a plurality of light-emitting units 140 which emit light having a peak at a first wavelength and a light-transmitting region located between the plurality of light-emitting units 140. In addition, the covering layer includes the optical function layer 170. A layer or a film which maybe included in the covering layer is, for example, a protective layer, a sealing film 182, or a resin layer 186 formed by molding or coating a resin.

As described above, although the embodiments and the example of the present invention have been set forthwith reference to the accompanying drawings, they are merely illustrative of the present invention, and various configurations other than those stated above can be adopted.

Exemplary reference embodiments will be appended below.

1-1. A light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which the reflecting layer has a higher light reflectance at the first wavelength than an average reflectance within a wavelength range of equal to or higher than 400 nm and equal to or lower than 700 nm.

1-2. A light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which a reflectance of the reflecting layer is equal to or greater than 30% with respect to light within a wavelength range between two wavelengths as upper and lower limits each having an intensity of one half of a peak intensity of the peak at the first wavelength.

1-3. A light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which a wavelength having a maximum reflectance in a reflection spectrum of light of the reflecting layer within a wavelength range of equal to or greater than 400 nm and equal to or less than 700 nm is located within a wavelength range between two wavelengths as upper and lower limits each having an intensity of one half of a peak intensity of the peak at the first wavelength.

1-4. A light-emitting device including:

a plurality of light-emitting units located between a light-transmitting first base material and a light-transmitting second base material, the light-emitting units emitting light having a peak at a first wavelength; and

a light-transmitting region located between the plurality of light-emitting units,

in which the second base material includes a reflecting layer, and

in which when a maximum reflectance in a reflection spectrum of light of the reflecting layer within a wavelength range of equal to or greater than 400 nm and equal to or less than 700 nm is Rₘₐₓ, the first wavelength is contained within the wavelength range having a reflectance of equal to or greater than Rₘₐₓ×0.5.

1-5. The light-emitting device according to any one of 1-1 to 1-4,

in which the light-emitting unit includes a light-transmitting first electrode, a light-shielding second electrode, and an organic layer located between the first electrode and the second electrode, and

in which the second electrode is located on a side of the first electrode opposite to the first base material.

1-6. The light-emitting device according to 1-5,

in which the light-transmitting region is a region that does not overlap the second electrode when viewed from a direction perpendicular to the first base material.

1-7. The light-emitting device according to any one of 1-1 to 1-6,

in which the reflecting layer is composed of a laminated film having a plurality of dielectric films that are laminated, or a metal film.

1-8. The light-emitting device according to 1-7,

in which the laminated film contains an inorganic material.

1-9. The light-emitting device according to any one of 1-1 to 1-8,

in which the reflecting layer is in contact with the light-emitting unit.

1-10. The light-emitting device according to any one of 1-1 to 1-9,

in which an average light transmittance of the reflecting layer is equal to or greater than 50% with respect to light within a wavelength range between two wavelengths each having one fifth of the intensity of a peak intensity at the peak at the first wavelength as upper and lower limits.

1-11. The light-emitting device according to anyone of 1-1 to 1-10,

in which the reflecting layer is formed in a region overlapping the light-transmitting region when viewed from a direction perpendicular to the first base material.

1-12. The light-emitting device according to anyone of 1-1 to 1-11,

in which the second base material includes a sealing film that covers the light-emitting unit, the sealing film being in contact with the light-emitting unit, and

in which the sealing film is the reflecting layer.

2-1. A light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which the reflecting layer has a higher light reflectance at the first wavelength than an average reflectance within a wavelength range of equal to or higher than 400 nm and equal to or lower than 700 nm.

2-2. A light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer,

in which a reflectance of the reflecting layer is equal to or greater than 30% with respect to light within a wavelength range between two wavelengths as upper and lower limits each having an intensity of one half of a peak intensity of the peak at the first wavelength.

2-3. A light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which a wavelength having a maximum reflectance in a reflection spectrum of light of the reflecting layer within a wavelength range of equal to or greater than 400 nm and equal to or less than 700 nm is located within a wavelength range between two wavelengths as upper and lower limits each having an intensity of one half of a peak intensity of the peak at the first wavelength.

2-4. A light-emitting device including:

a plurality of light-emitting units located between a light-transmitting base material and a light-transmitting covering layer, the light-emitting units emitting light having a peak at a first wavelength; and

a light-transmitting region located between the plurality of light-emitting units,

in which the covering layer includes a reflecting layer, and

in which when a maximum reflectance in a reflection spectrum of light of the reflecting layer within a wavelength range of equal to or greater than 400 nm and equal to or less than 700 nm is Rₘₐₓ, the first wavelength is contained within the wavelength range having a reflectance of equal to or greater than Rₘₐₓ×0.5.

2-5. The light-emitting device according to any one of 2-1 to 2-4,

in which the light-emitting unit includes a light-transmitting first electrode, a light-shielding second electrode, and an organic layer located between the first electrode and the second electrode, and

in which the second electrode is located on a side of the first electrode opposite to the base material.

2-6. The light-emitting device according to 2-5,

in which the light-transmitting region is a region that does not overlap the second electrode when viewed from a direction perpendicular to the base material.

2-7. The light-emitting device according to any one of 2-1 to 2-6,

in which the reflecting layer is composed of a laminated film having a plurality of dielectric films that are laminated, or a metal film.

2-8. The light-emitting device according to 2-7,

in which the laminated film contains an inorganic material.

2-9. The light-emitting device according to any one of 2-1 to 2-8,

in which the reflecting layer is in contact with the light-emitting unit.

2-10. The light-emitting device according to any one of 2-1 to 2-9,

in which an average light transmittance of the reflecting layer is equal to or greater than 50% with respect to light within a wavelength range between two wavelengths each having one fifth of the intensity of the peak intensity at the peak at the first wavelength as upper and lower limits.

2-11. The light-emitting device according to any one of 2-1 to 2-10,

in which the reflecting layer is formed in a region overlapping the light-transmitting region when viewed from a direction perpendicular to the base material.

2-12. The light-emitting device according to any one of 2-1 to 2-11,

in which the covering layer includes a sealing film that covers the light-emitting unit, the sealing film being in contact with the light-emitting unit, and

in which the sealing film is the reflecting layer.

1. A light-emitting device comprising:
a plurality of light-emitting units located between a light-transmitting first base material and a light-transmitting second base material, the light-emitting units emitting light having a peak at a first wavelength; and
a light-transmitting region located between the plurality of light-emitting units,
wherein the second base material comprises a reflecting layer, and
wherein the reflecting layer has a higher light reflectance at the first wavelength than an average reflectance within a wavelength range of equal to or higher than 400 nm and equal to or lower than 700 nm.

2. (canceled)

3. (canceled)

4. (canceled)

5. The light-emitting device according to claim 1.
wherein the light-emitting unit comprises a light-transmitting first electrode, a light-shielding second electrode, and an organic layer located between the first electrode and the second electrode, and
wherein the second electrode is located on a side of the first electrode opposite to the first base material.

6. The light-emitting device according to claim 5,
wherein the light-transmitting region is a region that does not overlap the second electrode when viewed from a direction perpendicular to the first base material.

7. The light-emitting device according to claim 1,
wherein the reflecting layer comprises a laminated film having a plurality of dielectric films that are laminated, or a metal film.

8. The light-emitting device according to claim 7,
wherein the laminated film comprises an inorganic material.

9. The light-emitting device according to claim 1,
wherein the reflecting layer is in contact with the light-emitting unit.

10. The light-emitting device according to claim 1,
wherein an average light transmittance of the reflecting layer is equal to or greater than 50% with respect to light within a wavelength range between two wavelengths each having one fifth of the intensity of the peak intensity at the peak as upper and lower limits.

11. The light-emitting device according to claim 1,
wherein the reflecting layer is formed in a region overlapping the light-transmitting region when viewed from a direction perpendicular to the first base material.

12. The light-emitting device according to claim 1,
wherein the second base material comprises a sealing film that covers the light-emitting unit, the sealing film being in contact with the light-emitting unit, and
wherein the sealing film is the reflecting layer.

13. A light-emitting device comprising:
a plurality of light-emitting units located between a light-transmitting base material and a light-transmitting covering layer, the light-emitting units emitting light having a peak at a first wavelength; and
a light-transmitting region located between the plurality of light-emitting units,
wherein the covering layer comprises a reflecting layer, and
wherein the reflecting layer has a higher light reflectance at the first wavelength than an average reflectance within a wavelength range of equal to or higher than 400 nm and equal to or lower than 700 nm.

14. (canceled)

15. (canceled)

16. (canceled)
